(19) United States
(12) Patent Application Publication
(10) Pub. No.: US 2024/0212580 A1
(43) Pub. Date: Jun. 27, 2024

(54) PIXEL CIRCUIT, DISPLAY PANEL AND DISPLAY APPARATUS

(71) Applicant: Shanghai Tianma Microelectronics Co., Ltd., Shanghai (CN)

(72) Inventor: Ji XU, Shanghai (CN)

(73) Assignee: Shanghai Tianma Microelectronics Co., Ltd., Shanghai (CN)

(21) Appl. No.: 18/128,282

(22) Filed: Mar. 30, 2023

(30) Foreign Application Priority Data
Dec. 23, 2022 (CN) 202211665986.5

(51) Int. Cl. G09G 3/32; H10K 59/131

(52) U.S. Cl. CPC G09G 3/32; H10K 59/131; G09G 2300/0842; G09G 2310/0202; G09G 2310/08; G09G 2330/021

(57) ABSTRACT

The embodiments of the present application provide a pixel circuit, a display panel and a display apparatus. The pixel circuit includes: a driving module including a first control terminal for receiving a control signal and a second control terminal for receiving an adjustment signal, in which a voltage value of the adjustment signal is a first voltage value when the driving module operates in a first stage and is a second voltage value when the driving module operates in a second stage, and the first voltage value is different from the second voltage value. The embodiments of the present application can increase the driving current of the pixel circuit.

### CROSS-REFERENCE TO RELATED APPLICATION

This application claims priority to Chinese Patent Application No. 202211665986.5, filed on Dec. 23, 2022, which is incorporated herein by reference in its entirety.

### TECHNICAL FIELD

The present application relates to the field of display technology, and particularly to a pixel circuit, a display panel and a display apparatus.

### BACKGROUND

With the continuous development of display technology, display panels are more and more widely applied, and user's demand for the display panels are greater and greater. A pixel circuit in a display panel plays a very important role in driving a light emitting element to emit light stably. The pixel circuit can provide a driving current to the light emitting element to drive the light emitting element to emit light.

Nonetheless, the existing pixel circuit has a relatively low driving current, which in turn leads to a low light emitting efficiency of the light emitting element.

### SUMMARY

The embodiments of the present application provide a pixel circuit, a display panel and a display apparatus.

In a first aspect, the embodiments of the present application provide a pixel circuit, including: a driving module including a first control terminal for receiving a control signal and a second control terminal for receiving an adjustment signal, in which a voltage value of the adjustment signal is a first voltage value when the driving module operates in a first stage and is a second voltage value when the driving module operates in a second stage, and the first voltage value is different from the second voltage value.

In a second aspect, the embodiments of the present application provide a display panel including a pixel circuit, the pixel circuit including: a driving module including a first control terminal for receiving a control signal and a second control terminal for receiving an adjustment signal, in which a voltage value of the adjustment signal is a first voltage value when the driving module operates in a first stage and is a second voltage value when the driving module operates in a second stage, and the first voltage value is different from the second voltage value.

In a third aspect, the embodiments of the present application provide a display apparatus including a display panel, the display panel including a pixel circuit, and the pixel circuit including: a driving module including a first control terminal for receiving a control signal and a second control terminal for receiving an adjustment signal, in which a voltage value of the adjustment signal is a first voltage value when the driving module operates in a first stage and is a second voltage value when the driving module operates in a second stage, and the first voltage value is different from the second voltage value.

### BRIEF DESCRIPTION OF THE DRAWINGS

In order to more clearly illustrate the technical solutions of the embodiments of the present application, the drawings to be used in the embodiments of the present application will be briefly introduced below. For those of ordinary skill in the art, other drawings can be obtained based on these drawings without inventive effort.

FIG. 1 shows a schematic circuit diagram of a pixel circuit according to the embodiments of the present application;

FIG. 2 shows another schematic circuit diagram of a pixel circuit according to the embodiments of the present application;

FIG. 3 shows yet another schematic circuit diagram of a pixel circuit according to the embodiments of the present application;

FIG. 4 shows yet another schematic circuit diagram of a pixel circuit according to the embodiments of the present application;

FIG. 5 shows yet another schematic circuit diagram of a pixel circuit according to the embodiments of the present application;

FIG. 6 shows yet another schematic circuit diagram of a pixel circuit according to the embodiments of the present application;

FIG. 7 shows yet another schematic circuit diagram of a pixel circuit according to the embodiments of the present application;

FIG. 8 shows a schematic driving timing diagram corresponding to the pixel circuit as shown in FIG. 7;

FIG. 9 shows yet another schematic circuit diagram of a pixel circuit according to the embodiments of the present application;

FIG. 10 shows a schematic driving timing diagram corresponding to the pixel circuit as shown in FIG. 9;

FIG. 11 shows a schematic partial sectional view of a display panel in which the pixel circuit according to the embodiments of the present application is located;

FIG. 12 shows another schematic partial sectional view of a display panel in which the pixel circuit according to the embodiments of the present application is located;

FIG. 13 shows yet another schematic partial sectional view of a display panel in which the pixel circuit according to the embodiments of the present application is located;

FIG. 14 shows yet another schematic partial sectional view of a display panel in which the pixel circuit according to the embodiments of the present application is located;

FIG. 15 shows a schematic structural diagram of a display panel according to the embodiments of the present application; and

FIG. 16 shows a schematic structural diagram of a display apparatus according to the embodiments of the present application.

### DETAILED DESCRIPTION

Features and exemplary embodiments of various aspects of the present application will be described in detail below. In order to make the objectives, technical solutions, and advantages of the present application clearer, the present application will be further described in detail below with reference to the drawings and specific embodiments. It should be understood that the specific embodiments described herein are merely intended to explain the present application, rather than to limit the present application. For those skilled in the art, the present application can be implemented without some of these specific details. The following description of the embodiments is merely to provide a better understanding of the present application by illustrating the examples of the present application.

It should be noted that, in the present application, relational terms, such as first and second, are used merely to distinguish one entity or operation from another entity or operation, without necessarily requiring or implying any actual such relationships or orders for these entities or operations. Moreover, the terms “comprise”, “include”, or any other variants thereof, are intended to represent a non-exclusive inclusion, such that a process, method, article or device including a series of elements includes not only those elements, but also other elements that are not explicitly listed or elements inherent to such a process, method, article or device. Without more constraints, the elements following an expression “comprise/include . . . ” do not exclude the existence of additional identical elements in the process, method, article or device that includes the elements.

It should be understood that the term “and/or” used herein merely represents an association relationship for describing the associated entities, indicating that there may be three kinds of relationships, for example, A and/or B may indicate A alone, both A and B, and B alone. In addition, the character “/” uses herein generally indicates that the associated entities before and after it are in an “or” relationship.

It should be noted that the transistor in the embodiments of the present application may be an N-type transistor or a P-type transistor. For the N-type transistor, the turn on level is a high level and the turn off level is a low level. That is, the N-type transistor is turned on when the gate of the N-type transistor is at the high level and is turned off when the gate of the N-type transistor is at the low level. For the P-type transistor, the turn on level is a low level and the turn off level is a high level. That is, the P-type transistor is turned on when the control terminal of the P-type transistor is at the low level and is turned off when the control terminal of the P-type transistor is at the high level. In specific implementations, the gate of the transistor is used as its control terminal, and depending on a signal of the gate and the type of the transistor, its first terminal may be used as the source and its second terminal may be used as the drain, or alternatively, its first terminal may be used as the drain and its second terminal may be used as the source, which is not limited herein. Further, the turn on level and the turn off level are used in a general sense in the embodiments of the present application, the turn on level refers to any level that can turn on the transistor, and the turn off level refers to any level that can cut off/turn off the transistor.

In the embodiments of the present application, the term “electrically connected” may indicate that two components are directly electrically connected, or that the two components are electrically connected via one or more other components.

In the embodiments of the present application, the first node, the second node and the third node are defined only to facilitate the description of the circuit structure, and are not actual circuit units.

It will be apparent to those skilled in the art that various modifications and variations can be made to the present application without departing from the gist or scope of the present application. Accordingly, the present application is intended to encompass the modifications and variations to the present application that fall within the scope of the appended claims (the claimed technical solutions) and equivalents thereof. It should be noted that the implementations provided by the embodiments of the present application can be combined with one another if there is no conflict.

Before the technical solutions provided by the embodiments of the present application are described, the problems in the art are first described in the present application to facilitate the understanding of the embodiments of the present application.

A pixel circuit in a display panel plays a very important role in driving a light emitting element to emit light stably. The pixel circuit can provide a driving current to the light emitting element to drive the light emitting element to emit light.

Nonetheless, the inventor of the present application found that the existing pixel circuit has a relatively low driving current, which in turn leads to a low light emitting efficiency of the light emitting element.

For example, for a light emitting element such as a micro light emitting diode (micro LED), a millimeter/sub-millimeter light emitting diode (mini LED) or an organic light emitting diode (OLED), the light emitting efficiency of the light emitting element is low if the light emitting element operates with a low current. Therefore, it is desired for the existing driving mode that the light emitting element operates with a high driving current, which requires increasing the driving current of the pixel circuit.

Based on the above findings of the inventor, the embodiments of the present application provide a pixel circuit, a display panel and a display apparatus, which can solve the problem of the low driving current of the pixel circuit.

The technical concept of the embodiments of the present application is that a driving module in a pixel circuit includes a first control terminal for receiving a control signal and a second control terminal for receiving an adjustment signal, in which a voltage value of the adjustment signal is a first voltage value when the driving module operates in a first stage and is a second voltage value when the driving module operates in a second stage, and the first voltage value is different from the second voltage value. In this way, by providing the adjustment signal with different voltage values in different stages, the offset state of the threshold voltage of the driving module can be adjusted, so that for example the threshold voltage of the driving module in the first stage is different from the threshold voltage of the driving module in the second stage, for example, the driving current of the pixel circuit can be (1/2)k(Vdata−VDD−ΔVth)², i.e., the driving current is offset by −ΔVth from its original value, in which ΔVth represents a change amount of the threshold voltage of the driving module between the first stage and the second stage. Since Vdata−VDD−ΔVth is less than Vdata−VDD, (1/2)k(Vdata−VDD−ΔVth)² is greater than (1/2)k(Vdata−VDD)², therefore the driving current of the pixel circuit can be increased, so as to improve the light emitting efficiency of the light emitting element.

A pixel circuit according to the embodiments of the present application is first described below.

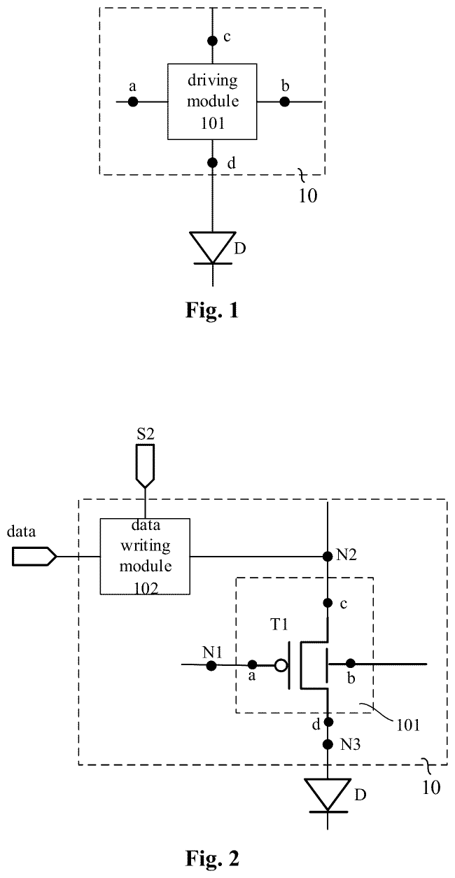

FIG. 1 shows a schematic circuit diagram of a pixel circuit according to the embodiments of the present application. As shown in FIG. 1, the pixel circuit 10 according to the embodiments of the present application may include a driving module 101. The driving module 101 may drive a light emitting element D to emit light. Exemplarily, the light emitting element D includes, but is not limited to, a micro light emitting diode (micro LED), a millimeter/sub-millimeter light emitting diode (mini LED), an organic light emitting diode (OLED), or a quantum dot light emitting diode (QLED), etc.

The driving module 101 may include a first control terminal (a) and a second control terminal (b). In some examples, the driving module 101 may be a thin film transistor (TFT), which has a dual-gate design, and specifically, the first control terminal (a) may be a first gate of the thin film transistor, and the second control terminal (b) may be a second gate of the thin film transistor. The first control terminal (a) may be configured to receive a control signal and the second control terminal (b) may be configured to receive an adjustment signal. Herein, the control signal may be configured to control the turn-on/turn-off of the driving module 101.

A voltage value of the adjustment signal may be a first voltage value V1 when the driving module 101 operates in a first stage. A voltage value of the adjustment signal may be a second voltage value V2 when the driving module 101 operates in a second stage. Herein, the first voltage value V1 is different from the second voltage value V2.

In this way, by providing the adjustment signal with different voltage values in different stages, the offset state of the threshold voltage Vth of the driving module can be adjusted, so that for example the threshold voltage Vth of the driving module in the first stage is different from the threshold voltage Vth of the driving module in the second stage, for example, the driving current of the pixel circuit can be (1/2)k(Vdata−VDD−ΔVth)², i.e., the driving current is offset by −ΔVth from its original value. Herein, k=μ*CO_{X}*W/L, in which W/L is a width-length ratio of a channel of the driving module, CO_{X} is the dielectric constant of an insulation layer of the channel, and μ is the carrier mobility of the channel. Vdata represents a voltage value of a data signal, VDD represents a voltage value of a first supply voltage signal, and ΔVth represents a change amount of the threshold voltage of the driving module between the first stage and the second stage. Since Vdata−VDD−ΔVth is less than Vdata−VDD, (1/2)k(Vdata−VDD−ΔVth)² is greater than (1/2)k(Vdata−VDD)², therefore the driving current of the pixel circuit can be increased, so as to improve the light emitting efficiency of the light emitting element.

Still referring to FIG. 1, according to some embodiments of the present application, optionally, the driving module 101 may be in an on state in both of the first stage and the second stage. Specifically, in the first stage and the second stage, the driving module 101 may be turned on, i.e., a first terminal (c) and a second terminal (d) of the driving module 101 may be conductive therebetween. Exemplarily, if the driving module 101 is a thin film transistor, the first terminal (c) of the driving module 101 may be the source of the thin film transistor, and the second terminal (d) of the driving module 101 may be the drain of the thin film transistor. Alternatively, the first terminal (c) of the driving module 101 may be the drain of the thin film transistor, and the second terminal (d) of the driving module 101 may be the source of the thin film transistor, which is not limited in the embodiments of the present application.

In this way, the driving module 101 is in the on state in both of the first stage and the second stage, which facilitates the adjusting of the offset state of the threshold voltage Vth of the driving module 101, so that for example the threshold voltage Vth of the driving module 101 in a light emitting stage is different from the threshold voltage Vth of the driving module 101 in a non-light emitting stage, so as to increase the driving current of the pixel circuit.

According to some embodiments of the present application, optionally, the first stage may include a data writing stage and the second stage may include a light emitting stage. The data writing stage is a stage during which the data signal is written to the pixel circuit, and the light emitting stage is a stage during which the light emitting element emits light, which will be described in detail below.

Still referring to FIG. 1, in the data writing stage, the adjustment signal with the first voltage value may be provided to the second control terminal (b) of the driving module 101. In the light emitting stage, the adjustment signal with the second voltage value may be provided to the second control terminal (b) of the driving module 101.

In this way, by providing the adjustment signal with different voltage values in the data writing stage and the light emitting stage, the threshold voltage of the driving module in the light emitting stage may be different from the threshold voltage of the driving module in the data writing stage, i.e. the threshold voltage of the driving module in the light emitting stage changes. Since the driving current of the pixel circuit is (1/2)*k(Vgs−Vth2)² and Vgs=Vdata+Vth1−VDD, the driving current of the pixel circuit is:

$$I = ( 1 / 2 ) * {k ( Vdata + Vth 1 - VDD - Vth 2 )}^{2} = ( 1 / 2 ) * {k ( Vdata - VDD + ( Vth 1 - Vth 2 ) )}^{2} = ( 1 / 2 ) * {k ( Vdata - VDD - Δ Vth )}^{2}$$

Herein, Vgs represents a difference between the voltage at the first control terminal of the driving module and the voltage at the source of the driving module, i.e., the gate voltage; Vth1 represents the threshold voltage of the driving module in the data writing stage; and Vth2 represents the threshold voltage of the driving module in the light emitting stage. Therefore, the threshold voltage Vth2 of the driving module in the light emitting stage is different from the threshold voltage Vth1 of the driving module in the data writing stage, the driving current of the pixel circuit can be increased.

According to some embodiments of the present application, optionally, an offset direction of the threshold voltage of the driving module 101 in the first stage may be different from an offset direction of the threshold voltage of the driving module 101 in the second stage. For example, the driving module 101 is a P-type transistor, in the first stage, the threshold voltage Vth of the driving module 101 may be negatively offset, i.e., the threshold voltage Vth of the driving module 101 may be decreased from its original value, i.e., Vth′−ΔVth1, in which Vth′ represents the original value of the threshold voltage Vth, and ΔVth1 represents a change amount of the threshold voltage of the driving module 101 in the first stage. In the second stage, the threshold voltage Vth of the driving module 101 may be positively offset, i.e., the threshold voltage Vth of the driving module 101 may be increased from its original value, i.e., Vth′+ΔVth2, in which ΔVth2 represents a change amount of the threshold voltage of the driving module 101 in the second stage.

If both of ΔVth1 and ΔVth2 are considered as positive values, it may be understood that the change amount of the threshold voltage of the driving module 101 in the first stage is −ΔVth1, and the change amount of the threshold voltage of the driving module 101 in the second stage is +ΔVth2. Accordingly, ΔVth=ΔVth2−(−ΔVth1).

In this way, the offset direction of the threshold voltage of the driving module 101 in the first stage is opposite to the offset direction of the threshold voltage of the driving module 101 in the second stage, so that a change amount ΔVth of the threshold voltage of the driving module between the first stage and the second stage is equal to ΔVth2 minus the negative ΔVth1, rather than the positive ΔVth1. Therefore, ΔVth is relatively great, so as to increase the driving current of the pixel circuit to a greater extent.

It should be noted that in some other embodiments, optionally, the offset direction of the threshold voltage of the driving module 101 in the first stage may be the same as the offset direction of the threshold voltage of the driving module 101 in the second stage, provided that ΔVth is greater than 0, i.e., Vdata−VDD−ΔVth is less than Vdata−VDD, which is not limited in the embodiments of the present application.

For convenience of understanding, in the following description, for example, the driving module 101 is a P-type transistor, the first stage is the data writing stage, and the second stage is the light emitting stage.

FIG. 2 shows another schematic circuit diagram of a pixel circuit according to the embodiments of the present application. As shown in FIG. 2, according to some embodiments of the present application, optionally, the driving module 101 may include a first transistor T1 which may be a transistor of first conductive type. The transistor of first conductive type may be a P-type transistor. The first control terminal (a) of the driving module 101 may include a first gate of the first transistor T1, and the second control terminal (b) of the driving module 101 may include a second gate of the first transistor T1. The first terminal (c) of the driving module 101 may include a first terminal of the first transistor T1, and the second terminal (d) of the driving module 101 may include a second terminal of the first transistor T1.

The first gate of the first transistor T1 is electrically connected with a first node N1, the first terminal of the first transistor T1 is electrically connected with a second node N2, and the second terminal of the first transistor T1 is electrically connected with a third node N3. The pixel circuit 10 may further include a data writing module 102, a control terminal of the data writing module 102 is electrically connected with a second scanning signal line S2, a first terminal of the data writing module 102 is electrically connected with a data signal line (data), and a second terminal of the data writing module 102 is electrically connected with the first terminal (c) of the driving module 101 (i.e., the second node N2).

In the data writing stage, the data writing module 102 is turned on under the control of the second scanning signal line S2 to transmit the data signal of the data signal line (data) to the second node N2. Since the first transistor T1 is turned on, the data signal is transmitted to the first node N1 through the turned-on first transistor T1. With the adjustment signal with the first voltage value V1, the threshold voltage of the first transistor T1 is negatively offset and is Vth1=Vth′−ΔVth1, in which Vth′ represents an original value of the threshold voltage of the first transistor T1, and ΔVth1 represents a difference between the threshold voltage of the first transistor T1 which has been adjusted by the adjustment signal with the first voltage value and the original value of the threshold voltage of the first transistor T1, i.e., a change amount of the threshold voltage of the first transistor T1 in the first stage. Therefore, in the data writing stage, the potential of the first node N1 is equal to Vdata+Vth′−ΔVth1, in which Vdata represents the voltage value of the data signal.

In the light emitting stage, the potential of the first node N1 remains the same. With the adjustment signal with the second voltage value V2, the threshold voltage of the first transistor T1 is positively offset and is Vth2=Vth′+ΔVth2, in which ΔVth2 represents a difference between the threshold voltage of the first transistor T1 which has been adjusted by the adjustment signal with the second voltage value and the original value of the threshold voltage of the first transistor T1, i.e., a change amount of the threshold voltage of the first transistor T1 in the second stage.

Therefore, the driving current of the pixel circuit is (1/2)*k(Vgs−Vth2)² and Vgs=Vdata+Vth1-VDD, the driving current of the pixel circuit is:

$$I = ( 1 / 2 ) * {k ( Vdata + Vth 1 - VDD - Vth 2 )}^{2} = ( 1 / 2 ) * {k ( Vdata - VDD - Δ Vth 1 - Δ Vth 2 )}^{2}$$

In this way, since Vdata−VDD−ΔVth1−ΔVth2 is less than Vdata−VDD, (1/2)*k(Vdata−VDD−ΔVth)² is greater than (1/2)*k(Vdata−VDD)², the driving current of the pixel circuit can be increased, so as to improve the light emitting efficiency of the light emitting element.

As previously described, in some embodiments, specifically, the driving module 101 may include the transistor of first conductive type, i.e., a P-type transistor. In the data writing stage, the data signal may be written to the transistor of first conductive type. As shown in FIG. 2, specifically, the data signal may be written to the first node N1 by the first terminal of the first transistor T1 through the turned-on first transistor T1. According to some embodiments of the present application, optionally, the first voltage value V1 may be greater than 0 V if the driving module 101 is the transistor of first conductive type. In the first stage, an adjustment signal greater than 0 V is provided to the second control terminal (b) of the driving module 101, so that the threshold voltage of the driving module 101 is negatively offset, that is, the threshold voltage Vth of the driving module 101 may be decreased from its original value, i.e., Vth′−ΔVth1. In this way, in the data writing stage, the potential of the first node N1 may be decreased from the original Vdata+Vth′ to Vdata+Vth′−ΔVth1. While in the light emitting stage, the potential of the first node N1 remains the same as Vdata+Vth′−ΔVth1. Since the driving module 101 is a P-type transistor, the conductive degree of the driving module 101 can be enhanced by decreasing the potential of the first node N1 in the data writing stage. While in the light emitting stage, the potential of the first node N1 remains the same, and the driving module 101 can still maintain a relative great conductive degree, so as to further increase the driving current of the driving module 101. Herein, the conductive degree may be used to indicate conductivity of the transistor, for example, the greater the conductive degree of the transistor, the greater the output current of the transistor.

As previously described, the first voltage value V1 is different from the second voltage value V2. For example, in some specific embodiments, the second voltage value V2 may be less than the first voltage value V1 if the driving module 101 is the transistor of first conductive type.

That is, in the first stage, by providing an adjustment signal with a relatively large voltage value, the threshold voltage Vth of the driving module 101 is negatively offset and decreased to a greater extent, so as to decrease the potential of the first node N1 to a greater extent and increase the driving current of the driving module 101.

In some specific embodiments, optionally, if the driving module 101 is the transistor of first conductive type, the first voltage value V1 may be greater than 0 V and the second voltage value V2 may be less than 0 V.

In this way, in the second stage, an adjustment signal less than 0 V is provided to the second control terminal (b) of the driving module 101, so that the threshold voltage of the driving module 101 is positively offset, that is, the threshold voltage Vth of the driving module 101 may be increased from its original value, i.e., Vth′+ΔVth2. As analyzed above, the offset direction of the threshold voltage of the driving module 101 in the first stage is opposite to the offset direction of the threshold voltage of the driving module 101 in the second stage, so that a change amount ΔVth of the threshold voltage of the driving module between the first stage and the second stage is equal to ΔVth2 minus the negative ΔVth1, rather than the positive ΔVth1. Therefore, ΔVth is relatively great, so as to increase the driving current of the pixel circuit to a greater extent.

The inventor of the present application further found that the voltage value of the adjustment signal received by the second control terminal (b) of the driving module 101 may have less effect on the potential of the first control terminal (a) of the driving module 101. In view of this, the present application considers that the voltage value of the adjustment signal may be set close to the potential of the first node N1 in the data writing stage or the light emitting stage, so as to ensure the stability of the potential of the first node N1.

Specifically, according to some embodiments of the present application, optionally, if the driving module 101 is the transistor of first conductive type, the first voltage value may be in a range of 0 V to 10 V and/or the second voltage value may be in a range of −10 V to 0 V. For example, in some specific examples, the first voltage value may be 8 V and the second voltage value may be −7 V, which is not limited in the embodiments of the present application.

In this way, by setting the first voltage value to be in a range of 0 V to 10 V and/or the second voltage value to be in a range of −10 V to 0 V, on the one hand, the voltage transmitted by the signal line in the display panel is generally between −10V and 10V, therefore the signal line already in the display panel can be reused to provide the adjustment signal, which is beneficial to the wiring design and cost saving; on the other hand, the voltage value of the adjustment signal is selected to be relatively small, which can reduce power consumption; and moreover, in the first stage and/or the second stage, the effect of a relatively great difference compared with the potential of the first control terminal (a) of the driving module 101 (i.e., the first node N1) on the potential of the first node N1 can be avoided, so as to ensure the stability of the potential of the first node N1.

FIG. 3 shows yet another schematic circuit diagram of a pixel circuit according to the embodiments of the present application. As shown in FIG. 3, unlike the embodiments as shown in FIG. 2, according to some embodiments of the present application, optionally, the driving module 101 may include a first transistor T1 which may be a transistor of second conductive type. The transistor of second conductive type may be an N-type transistor. The first control terminal (a) of the driving module 101 may include a first gate of the first transistor T1, and the second control terminal (b) of the driving module 101 may include a second gate of the first transistor T1. The first terminal (c) of the driving module 101 may include a first terminal of the first transistor T1, and the second terminal (d) of the driving module 101 may include a second terminal of the first transistor T1.

The first gate of the first transistor T1 is electrically connected with a first node N1, the first terminal of the first transistor T1 is electrically connected with a second node N2, and the second terminal of the first transistor T1 is electrically connected with a third node N3. The pixel circuit 10 may further include a data writing module 102, a control terminal of the data writing module 102 is electrically connected with a second scanning signal line S2, a first terminal of the data writing module 102 is electrically connected with a data signal line (data), and a second terminal of the data writing module 102 is electrically connected with the first terminal (c) of the driving module 101 (i.e., the second node N2).

In the data writing stage, the data writing module 102 is turned on under the control of the second scanning signal line S2 to transmit the data signal of the data signal line (data) to the second node N2. Since the first transistor T1 is turned on, the data signal is transmitted to the first node N1 through the turned-on first transistor T1.

The first voltage value may be less than 0 V if the driving module 101 is the transistor of second conductive type. In the first stage, an adjustment signal less than 0 V is provided to the second control terminal (b) of the driving module 101, so that the threshold voltage of the driving module 101 is positively offset, that is, the threshold voltage Vth of the driving module 101 may be increased from its original value, i.e., Vth′+ΔVth1. In this way, in the data writing stage, the potential of the first node N1 may be increased from the original Vdata+Vth′ to Vdata+Vth′+ΔVth1. While in the light emitting stage, the potential of the first node N1 remains the same as Vdata+Vth′+ΔVth1. Since the driving module 101 is an N-type transistor, the conductive degree of the driving module 101 can be enhanced by increasing the potential of the first node N1 in the data writing stage. While in the light emitting stage, the potential of the first node N1 remains the same, and the driving module 101 can still maintain a relative great conductive degree, so as to further increase the driving current of the driving module 101.

As previously described, the first voltage value V1 is different from the second voltage value V2. For example, in some specific embodiments, the second voltage value V2 may be greater than the first voltage value V1 if the driving module 101 is the transistor of second conductive type.

That is, in the first stage, by providing an adjustment signal with a relatively small negative voltage value, the threshold voltage Vth of the driving module 101 is positively offset and increased to a greater extent, so as to increase the potential of the first node N1 to a greater extent and increase the driving current of the driving module 101.

In some specific embodiments, optionally, if the driving module 101 is the transistor of second conductive type, the first voltage value V1 may be less than 0 V and the second voltage value V2 may be greater than 0 V.

In this way, in the second stage, an adjustment signal greater than 0 V is provided to the second control terminal (b) of the driving module 101, so that the threshold voltage of the driving module 101 is negatively offset, that is, the threshold voltage Vth of the driving module 101 may be decreased from its original value, i.e., Vth′−ΔVth2. ΔVth=|−ΔVth2−ΔVth1|. The offset direction of the threshold voltage of the driving module 101 in the first stage is opposite to the offset direction of the threshold voltage of the driving module 101 in the second stage, so that a change amount ΔVth of the threshold voltage of the driving module between the first stage and the second stage is equal to the absolute value of the negative ΔVth2 (rather than the positive ΔVth2) minus ΔVth1. Therefore, ΔVth is relatively great, so as to increase the driving current of the pixel circuit to a greater extent.

As previously described, the voltage value of the adjustment signal received by the second control terminal (b) of the driving module 101 may have less effect on the potential of the first control terminal (a) of the driving module 101. In view of this, the present application considers that the voltage value of the adjustment signal may be set close to the potential of the first node N1 in the data writing stage or the light emitting stage, so as to ensure the stability of the potential of the first node N1.

Specifically, according to some embodiments of the present application, optionally, if the driving module 101 is the transistor of second conductive type, the first voltage value may be in a range of −10 V to 0 V and/or the second voltage value may be in a range of 0 V to 10 V. For example, in some specific examples, the first voltage value may be −7 V and the second voltage value may be 8 V, which is not limited in the embodiments of the present application.

In this way, by setting the first voltage value to be in a range of −10 V to 0 V and/or the second voltage value to be in a range of 0 V to 10 V, on the one hand, the voltage transmitted by the signal line in the display panel is generally between −10V and 10V, therefore the signal line already in the display panel can be reused to provide the adjustment signal, which is beneficial to the wiring design and cost saving; on the other hand, the voltage value of the adjustment signal is selected to be relatively small, which can reduce power consumption; and moreover, in the first stage and/or the second stage, the effect of a relatively great difference compared with the potential of the first control terminal (a) of the driving module 101 (i.e., the first node N1) on the potential of the first node N1 can be avoided, so as to ensure the stability of the potential of the first node N1.

The circuit structure of the pixel circuit 10 is described below in combination with some specific embodiments.

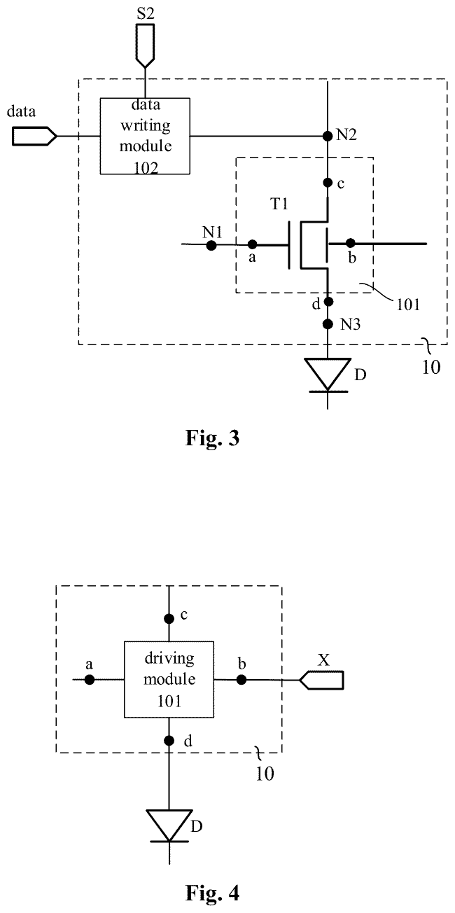

FIG. 4 shows yet another schematic circuit diagram of a pixel circuit according to the embodiments of the present application. As shown in FIG. 4, according to some embodiments of the present application, optionally, the second control terminal (b) of the driving module 101 may provide an adjustment signal through the adjustment signal line X. Specifically, the second control terminal (b) of the driving module 101 may be electrically connected with the adjustment signal line X and configured to receive the adjustment signal provided by the adjustment signal line. The adjustment signal may be configured to adjust the offset state of the threshold voltage of the driving module 101, i.e., the adjustment signal may be configured to control the threshold voltage of the driving module to be negatively offset or positively offset. In other words, the adjustment signal may be configured to adjust the bias state of the threshold voltage of the driving module 101, i.e., the adjustment signal may be configured to control the threshold voltage of the driving module to be negatively biased or positively biased.

In this way, with the adjustment signal provided to the second control terminal (b) of the driving module 101 by the adjustment signal line X, the offset state of the threshold voltage Vth of the driving module can be adjusted, so that for example the threshold voltage Vth of the driving module in the first stage is different from the threshold voltage Vth of the driving module in the second stage, so as to increase the driving current of the pixel circuit.

FIG. 5 shows yet another schematic circuit diagram of a pixel circuit according to the embodiments of the present application. As shown in FIG. 5, according to some embodiments of the present application, optionally, the pixel circuit 10 may further include a switching module 50. A control terminal of the switching module 50 may be electrically connected with a light emitting control signal line EM or a scanning signal line S, and a first terminal of the switching module 50 may be electrically connected with a first terminal (c) or a second terminal (d) of the driving module 101. As shown in FIG. 5, for example, the first terminal of the switching module 50 is electrically connected with the first terminal (c) of the driving module 101. The switching module 50 may be turned on in response to the control of the light emitting control signal line EM or the scanning signal line S.

As shown in FIG. 5, the adjustment signal line X may reuse the light emitting control signal line EM or the scanning signal line S.

For example, for a low temperature poly-silicon (LTPS) display panel, the voltage values of the light emitting control signal output by the light emitting control signal line EM in the first stage and the second stage are different (e.g., the potentials are opposite). Therefore, the adjustment signal line X may reuse the light emitting control signal line EM. Herein, in the LTPS display panel, a plurality of transistors in the pixel circuit are all LTPS transistors.

For example, for a low temperature polycrystalline oxide (LTPO) display panel, the voltage values of the light emitting control signal output by the light emitting control signal line EM or the scanning signal line to which an oxide transistor (for example, an indium gallium zinc oxide transistor, i.e., an IGZO transistor) is connected in the first stage and the second stage are different (e.g., the potentials are opposite). Therefore, the adjustment signal line X may reuse the light emitting control signal line EM or the scanning signal line to which the oxide transistor is connected. Herein, in the LTPO display panel, a part of the transistors in the pixel circuit are LTPS transistors, and another part of the transistors are oxide transistors.

No matter for the LTPS display panel or the LTPO display panel, the adjustment signal line X may be an additional signal line, or alternatively, the adjustment signal line X may reuse other signal lines except the light emitting control signal line EM or the scanning signal line S, such as a clock signal line, which is not limited in the embodiments of the present application.

In this way, the adjustment signal line X reuses the light emitting control signal line EM or the scanning signal line S, which can reduce the number of signal lines, save wiring space and reduce production costs.

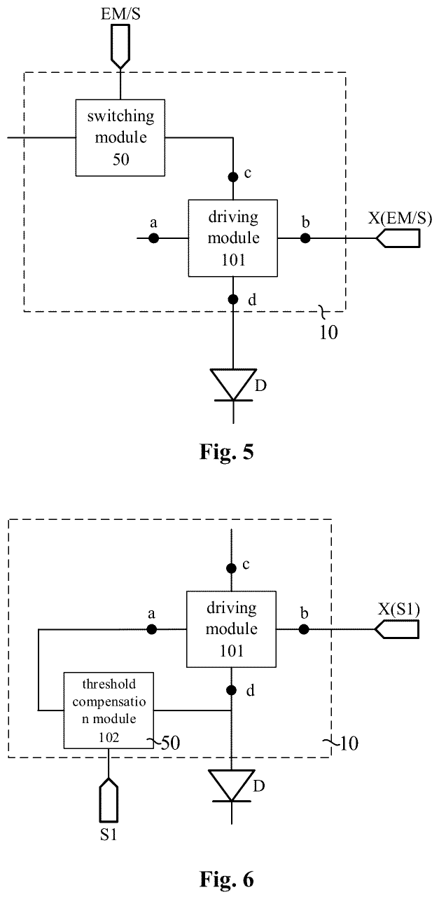

FIG. 6 shows yet another schematic circuit diagram of a pixel circuit according to the embodiments of the present application. As shown in FIG. 6, in some specific embodiments, optionally, the switching module 50 may include a threshold compensation module 102. A control terminal of the threshold compensation module 102 is electrically connected with a first scanning signal line S1, a first terminal of the threshold compensation module 102 is electrically connected with the first control terminal (a) of the driving module 101, and a second terminal of the threshold compensation module 102 is electrically connected with the second terminal (d) of the driving module 101. In the data writing stage, the threshold compensation module 102 may be turned on to connect the first control terminal (a) to the second terminal (d) of the driving module 101, so as to achieve threshold voltage compensation for the driving module 101.

The threshold compensation module 102 and the driving module 101 may be transistors of different conductivity types. For example, the threshold compensation module 102 may be an N-type transistor and the driving module 101 is a P-type transistor. Further, for example, the threshold compensation module 102 may be a P-type transistor and the driving module 101 is an N-type transistor.

For example, the threshold compensation module 102 is an N-type transistor and the driving module 101 is a P-type transistor, in the data writing stage, the first scanning signal line S1 may provide a high level (i.e., a positive potential), and the threshold compensation module 102 is turned on in response to the high level of the first scanning signal line S1. In the light emitting stage, the first scanning signal line S1 may provide a low level (i.e., a negative potential), and the threshold compensation module 102 is turned off in response to the low level of the first scanning signal line S1.

Therefore, the adjustment signal line X may reuse the first scanning signal line S1, the number of signal lines is reduced, and moreover, the voltage values of the adjustment signal in the data writing stage and the light emitting stage are different, so as to further increase the driving current of the pixel circuit.

In some embodiments, the threshold compensation module 102 may be an oxide transistor and the driving module 101 may be a LTPS transistor, i.e., the embodiments as shown in FIG. 6 may be applied to a LTPO display panel.

The inventor of the present application further found that the width-length ratio of the channel of the existing driving module 101 (or driving transistor) is usually 1/10, and such a small width-length limits the driving current of the pixel circuit.

In view of this, according to some embodiments of the present application, optionally, the driving module may include a driving transistor, and a width-length ratio of a channel of the driving transistor is greater than 1/10. The driving module includes, but is not limited to, the driving module 101 as shown in any one of FIGS. 1 to 6.

In this way, by increasing the width-length ratio of the channel of the driving transistor, the driving current of the pixel circuit can be further increased. In addition, the inventor of the present application further found that if merely the width-length ratio of the channel of the driving transistor is increased, the output current of the pixel circuit would not be increased proportionally to the increase of the width-length ratio. The reason is that when the data signal is written, the charging rate of the driving transistor is increased as the increase of the width-length ratio of the channel of the driving transistor, causing the potential of the first node N1 node to be higher, and thus affecting the output current of the pixel circuit.

With the increase of the width-length ratio of the channel of the driving transistor, together with the scheme according to the embodiments of the present application for increasing the driving current of the pixel circuit by adjusting the voltage value of the adjustment signal, the potential of the first node N1 node would not be increased due to the increase of the width-length ratio of the channel of the driving transistor, so that the output current of the pixel circuit can be increased, for example, proportionally to the increase of the width-length ratio to further enhance the improvement.

The pixel circuit 10 according to the embodiments of the present application is described below in combination with a 7T1C pixel circuit. It may be understood that the pixel circuit 10 according to the embodiments of the present application includes, but is not limited to, the 7T1C pixel circuit, but may further be a 7T2C pixel circuit, an 8T1C pixel circuit, a 9T1C pixel circuit, or other types of pixel circuits, which is not limited in the embodiments of the present application.

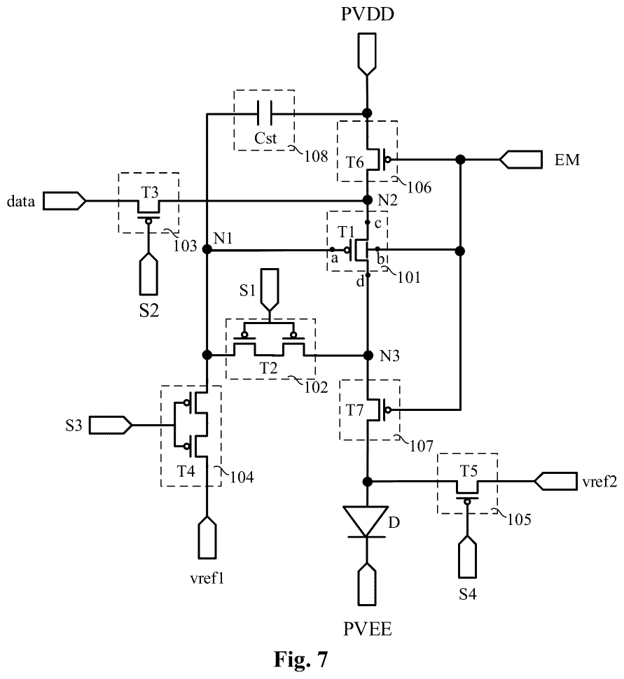

FIG. 7 shows yet another schematic circuit diagram of a pixel circuit according to the embodiments of the present application. As shown in FIG. 7, in some specific embodiments, optionally, the first control terminal (a) of the driving module 101 is electrically connected with the first node N1, the second control terminal (b) of the driving module 101 is electrically connected with the light emitting control signal line EM, the first terminal (c) of the driving module 101 is electrically connected with the second node N2, and the second terminal (d) of the driving module 101 is electrically connected with the third node N3.

The pixel circuit 10 may further include a threshold compensation module 102, a data writing module 103, a first resetting module 104, a second resetting module 105, a first light emitting control module 106, a second light emitting control module 107, and a storage module 108.

A control terminal of the threshold compensation module 102 is electrically connected with a first scanning signal line S1, a first terminal of the threshold compensation module 102 is electrically connected with the first control terminal (a) of the driving module 101 (i.e., the first node N1), and a second terminal of the threshold compensation module 102 is electrically connected with a second terminal (d) of the driving module 101 (i.e., the third node N3).

A control terminal of the data writing module 103 is electrically connected with a second scanning signal line S2, a first terminal of the data writing module 103 is electrically connected with a data signal line (data), and a second terminal of the data writing module 103 is electrically connected with a first terminal (c) of the driving module 101 (i.e., the second node N2).

A control terminal of the first resetting module 104 is electrically connected with a third scanning signal line S3, a first terminal of the first resetting module 104 is electrically connected with a first reference voltage signal line vref1, and a second terminal of the first resetting module 104 is electrically connected with the first control terminal (a) of the driving module 101 (i.e., the first node N1).

A control terminal of the second resetting module 105 is electrically connected with a fourth scanning signal line S4, a first terminal of the second resetting module 105 is electrically connected with a second reference voltage signal line vref2, and a second terminal of the second resetting module 105 is electrically connected with a first electrode of a light emitting element D. Herein, the first electrode of the light emitting element D may be the anode of the light emitting element D, and a second electrode of the light emitting element D may be the cathode of the light emitting element D. The second electrode of the light emitting element D may be electrically connected with a second supply voltage signal line PVEE.

A control terminal of the first light emitting control module 106 is electrically connected with a light emitting control signal line EM, a first terminal of the first light emitting control module 106 is electrically connected with a first supply voltage signal line PVDD, and a second terminal of the first light emitting control module 106 is electrically connected with the first terminal (c) of the driving module 101 (i.e., the second node N2).

A control terminal of the second light emitting control module 107 is electrically connected with the light emitting control signal line EM, a first terminal of the second light emitting control module 107 is electrically connected with the second terminal (d) of the driving module 101 (i.e., the third node N3), and a second terminal of the second light emitting control module 107 is electrically connected with the first electrode of the light emitting element D.

A first terminal of the storage module 108 is electrically connected with the first supply voltage signal line PVDD, and a second terminal of the storage module 108 is electrically connected with the first control terminal (a) of the driving module 101 (i.e., the first node N1).

In some examples, the first scanning signal line S1, the second scanning signal line S2, and the fourth scanning signal line S4 can be reused, so as to reduce the number of signal lines and save wiring space.

In the embodiments as shown in FIG. 7, the driving module 101, the threshold compensation module 102, the data writing module 103, the first resetting module 104, the second resetting module 105, the first light emitting control module 106, and the second light emitting control module 107 may all be P-type transistors. Exemplarily, the driving module 101, the threshold compensation module 102, the data writing module 103, the first resetting module 104, the second resetting module 105, the first light emitting control module 106, and the second light emitting control module 107 may all be LTPS transistors.

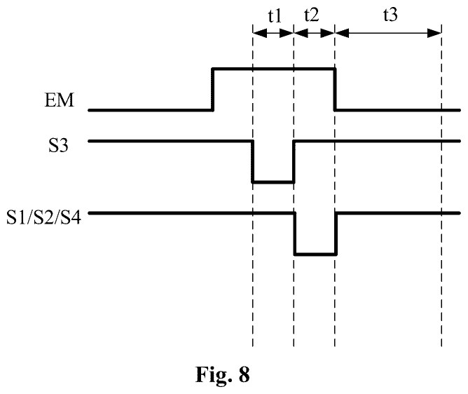

FIG. 8 shows a schematic driving timing diagram corresponding to the pixel circuit as shown in FIG. 7. As shown in FIG. 8, according to some embodiments of the present application, optionally, an operation process of the pixel circuit includes an initialization stage t1, a data writing stage t2, and a light emitting stage t3. In the initialization stage t1, the third scanning signal line S3 outputs a low level, and the first resetting module 104 is turned on in response to the low level of the third scanning signal line S3 to transmit the first reference voltage signal of the first reference voltage signal line vref1 to the first node N1, so as to initialize the first node N1.

In the data writing stage t2, the first scanning signal line S1, the second scanning signal line S2 and the fourth scanning signal line S4 output a low level, and the light emitting control signal line EM outputs a high level. The threshold compensation module 102 is turned on in response to the low level of the first scanning signal line S1, the data writing module 103 is turned on in response to the low level of the second scanning signal line S2, and the driving module 101 is turned on in response to the low level of the first node N1. The data signal of the data signal line (data) is written to the second node N2 and is transmitted to the first node N1 through the turned-on driving module 101 and the turned-on threshold compensation module 102, so as to achieve the data signal writing and threshold voltage compensation for the driving module 101.

Since the light emitting control signal line EM to which the second control terminal (b) of the driving module 101 is connected is at the high level (i.e., a positive potential), the threshold voltage of the driving module 101 is negatively offset and is Vth1=Vth′−ΔVth1, in which Vth′ represents an original value of the threshold voltage of the driving module 101, and ΔVth1 represents a difference between the threshold voltage of the driving module 101 which has been adjusted by the adjustment signal with the first voltage value and the original value of the threshold voltage of the driving module 101, i.e., a change amount of the threshold voltage of the driving module 101 in the data writing stage. Therefore, in the data writing stage, the potential of the first node N1 is equal to Vdata+Vth′−ΔVth1, in which Vdata represents the voltage value of the data signal.

In the data writing stage t2, the second resetting module 105 is turned on in response to the low level of the fourth scanning signal line S4 to transmit the second reference voltage signal of the second reference voltage signal line vref2 to the first electrode of the light emitting element D, so as to initialize the first electrode of the light emitting element D.

In the light emitting stage t3, the light emitting control signal line EM outputs a low level, the first light emitting control module 106 and the second light emitting control module 107 are turned on in response to the low level of the light emitting control signal line EM, the driving module 101 is turned on in response to the low level of the first node N1, and the light emitting element D emits light. Since the light emitting control signal line EM to which the second control terminal (b) of the driving module 101 is connected is at the low level (i.e., a negative potential), the threshold voltage of the driving module 101 is positively offset and is Vth2=Vth′+ΔVth2, in which ΔVth2 represents a difference between the threshold voltage of the driving module 101 which has been adjusted by the adjustment signal with the second voltage value and the original value of the threshold voltage of the driving module 101, i.e., a change amount of the threshold voltage of the f driving module 101 in the second stage.

Therefore, the driving current of the pixel circuit is (1/2)*k(Vgs−Vth2+ΔV)² and Vgs=Vdata+Vth1-VDD, the driving current of the pixel circuit is:

$$I = ( 1 / 2 ) * {k ( Vdata + Vth 1 - VDD - Vth 2 + Δ V )}^{2} = ( 1 / 2 ) * {k ( Vdata - V D D - Δ Vth 1 - Δ Vth 2 + Δ V )}^{2}$$

Herein, ΔV represents a deviation of the actual potential from the ideal potential due to the charging rate and the parasitic capacitive coupling within the pixel circuit. Under a condition the width-length ratio of the channel of the driving module is increased, the charging rate is increased and the potential of the first node N1 is higher, i.e., ΔV is greater, which will reduce the driving current of the pixel circuit to some extent. With the scheme according to the embodiments of the present application for increasing the driving current of the pixel circuit by adjusting the voltage value of the adjustment signal, the potential of the first node N1 in the data writing stage and the light emitting stage may be decreased to Vdata+Vth′−ΔVth1, and the driving current is increased to (1/2)*k(Vdata−VDD−ΔVth1-ΔVth2+ΔV)², so that the driving current of the pixel circuit can be increased, for example, proportionally to the increase of the width-length ratio.

Still referring to FIG. 7, in some specific embodiments, the driving module 101 may include a first transistor T1, the threshold compensation module 102 may include a second transistor T2, the data writing module 103 may include a third transistor T3, the first resetting module 104 may include a fourth transistor T4, the second resetting module 105 may include a fifth transistor T5, the first light emitting control module 106 may include a sixth transistor T6, the second light emitting control module 107 may include a seventh transistor T7, and the storage module 108 may include a storage capacitor Cst. Reference is made to FIG. 7 and the above description of various modules for connections of the various transistors, which will not be repeated herein.

Still referring to FIG. 7, in some specific embodiments, both of the second transistor T2 and the fourth transistor T4 to which the first node N1 is connected may be dual-gate transistors, so as to further reduce the leakage current of the first node N1 and ensure the stability of the potential of the first node N1.

In the embodiments as shown in FIG. 7, all of the first transistor T1 to the seventh transistor T7 may be P-type transistors. All of the first transistor T1 to the seventh transistor T7 may be LTPS transistors, i.e., the embodiments as shown in FIG. 7 may be applied to a LTPS display panel.

In some other embodiments, the second transistor T2 and the fourth transistor T4 may be N-type transistors, and other transistors except the second transistor T2 and the fourth transistor T4 may be P-type transistors.

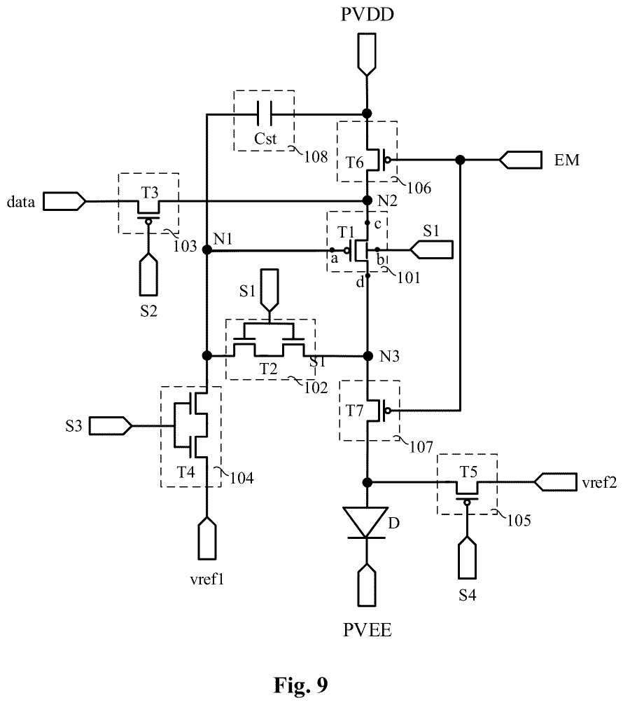

FIG. 9 shows a schematic circuit diagram of a pixel circuit in which the second transistor T2 and the fourth transistor T4 are N-type transistors. As shown in FIG. 9, unlike the embodiments as shown in FIG. 7, according to some other embodiments of the present application, optionally, the second control terminal (b) of the driving module 101 may be electrically connected with the first scanning signal line S1 if the threshold compensation module 102 and the first resetting module 104 are N-type transistors. Other connections in FIG. 9 are the same as those in FIG. 7, which will not be described herein.

In some examples, the second scanning signal line S2 and the fourth scanning signal line S4 can be reused, so as to reduce the number of signal lines and save wiring space.

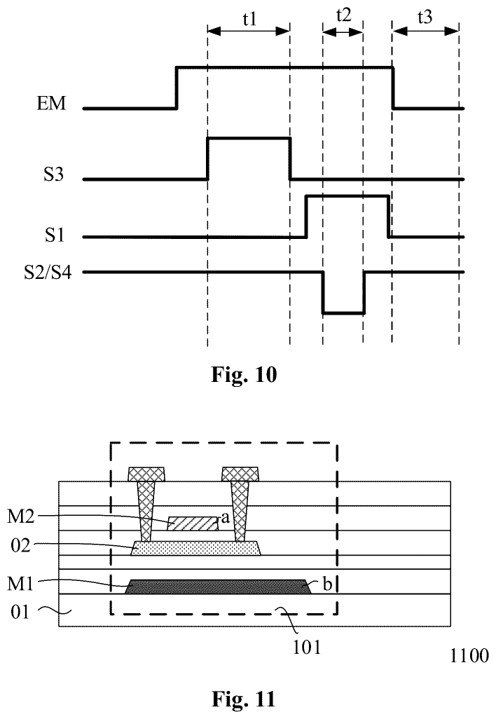

FIG. 10 shows a schematic driving timing diagram of the pixel circuit as shown in FIG. 9. As shown in FIG. 10, according to some embodiments of the present application, optionally, an operation process of the pixel circuit includes an initialization stage t1, a data writing stage t2, and a light emitting stage t3. In the initialization stage t1, the third scanning signal line S3 outputs a high level, and the first resetting module 104 is turned on in response to the high level of the third scanning signal line S3 to transmit the first reference voltage signal of the first reference voltage signal line vref1 to the first node N1, so as to initialize the first node N1.

In the data writing stage t2, the first scanning signal line S1 outputs a high level, the second scanning signal line S2 and the fourth scanning signal line S4 output a low level, and the light emitting control signal line EM outputs a high level. The threshold compensation module 102 is turned on in response to the high level of the first scanning signal line S1, the data writing module 103 is turned on in response to the low level of the second scanning signal line S2, and the driving module 101 is turned on in response to the low level of the first node N1. The data signal of the data signal line (data) is written to the second node N2 and is transmitted to the first node N1 through the turned-on driving module 101 and the turned-on threshold compensation module 102, so as to achieve the data signal writing and threshold voltage compensation for the driving module 101.

Since the first scanning signal line S1 to which the second control terminal (b) of the driving module 101 is connected is at the high level (i.e., a positive potential), the threshold voltage of the driving module 101 is negatively offset and is Vth1=Vth′−ΔVth1, in which Vth′ represents an original value of the threshold voltage of the driving module 101, and ΔVth1 represents a difference between the threshold voltage of the driving module 101 which has been adjusted by the adjustment signal with the first voltage value and the original value of the threshold voltage of the driving module 101, i.e., a change amount of the threshold voltage of the driving module 101 in the data writing stage. Therefore, in the data writing stage, the potential of the first node N1 is equal to Vdata+Vth′−ΔVth1, in which Vdata represents the voltage value of the data signal.

In the data writing stage t2, the second resetting module 105 is turned on in response to the low level of the fourth scanning signal line S4 to transmit the second reference voltage signal of the second reference voltage signal line vref2 to the first electrode of the light emitting element D, so as to initialize the first electrode of the light emitting element D.

In the light emitting stage t3, the first scanning signal line S1 and the light emitting control signal line EM output a low level, the first light emitting control module 106 and the second light emitting control module 107 are turned on in response to the low level of the light emitting control signal line EM, the driving module 101 is turned on in response to the low level of the first node N1, and the light emitting element D emits light. Since the first scanning signal line S1 to which the second control terminal (b) of the driving module 101 is connected is at the low level (i.e., a negative potential), the threshold voltage of the driving module 101 is positively offset and is Vth2=Vth′+ΔVth2, in which ΔVth2 represents a difference between the threshold voltage of the driving module 101 which has been adjusted by the adjustment signal with the second voltage value and the original value of the threshold voltage of the driving module 101, i.e., a change amount of the threshold voltage of the f driving module 101 in the second stage.

Therefore, the driving current of the pixel circuit is (1/2)*k(Vgs−Vth2+ΔV)² and Vgs=Vdata+Vth1-VDD, the driving current of the pixel circuit is:

$$I = ( 1 / 2 ) * {k ( Vdata + Vth 1 - VDD - Vth 2 + Δ V )}^{2} = ( 1 / 2 ) * {k ( Vdata - V D D - Δ Vth 1 - Δ Vth 2 + Δ V )}^{2}$$

Herein, ΔV represents a deviation of the actual potential from the ideal potential due to the charging rate and the parasitic capacitive coupling within the pixel circuit. Under a condition the width-length ratio of the channel of the driving module is increased, the charging rate is increased and the potential of the first node N1 is higher, i.e., ΔV is greater, which will reduce the driving current of the pixel circuit to some extent. With the scheme according to the embodiments of the present application for increasing the driving current of the pixel circuit by adjusting the voltage value of the adjustment signal, the potential of the first node N1 in the data writing stage and the light emitting stage may be decreased to Vdata+Vth′−ΔVth1, and the driving current is increased to (1/2)*k(Vdata−VDD−ΔVth1-ΔVth2+ΔV)², so that the driving current of the pixel circuit can be increased, for example, proportionally to the increase of the width-length ratio.

In the embodiments as shown in FIG. 9, the second transistor T2 and the fourth transistor T4 may be N-type transistors, and other transistors except the second transistor T2 and the fourth transistor T4 may be P-type transistors. Exemplarily, the second transistor T2 and the fourth transistor T4 may be IGZO transistors, and other transistors except the second transistor T2 and the fourth transistor T4 may be LTPS transistors, i.e., the embodiments as shown in FIG. 9 may be applied to a LTPO display panel.

Film layer structure of a display panel in which the pixel circuit 10 according to the embodiments of the present application is located is illustrated below in combination with some specific embodiments.

FIG. 11 shows a schematic partial sectional view of a display panel in which the pixel circuit according to the embodiments of the present application is located. As shown in FIG. 11, according to some embodiments of the present application, optionally, the pixel circuit according to the embodiments of the present application may be applied to a display panel 1100, which includes at least a substrate 01, a first metal layer M1, an active layer 02, and a second metal layer M2 that are stacked. The substrate 01 is primarily configured to support the layers and may include a flexible substrate made of a material such as polyethylene terephthalate (PET), polyphenylene sulfide (PPS), polyarylate, or polyimide (PI) or a rigid substrate made of a material such as glass. The material of the first metal layer M1 and the second metal layer M2 may be a metallic material, for example, including, but not limited to, a single layer or a plurality of layers of gold (Au), silver (Ag), copper (Cu), nickel (Ni), platinum (Pt), palladium (Pd), aluminum (Al), molybdenum (MO), or chromium (Cr). In some specific examples, for example, the material of the first metal layer M1 may be molybdenum (MO). The material of the active layer 02 may be a semiconductor material, such as an amorphous silicon material, a polycrystalline silicon material, or a metal oxide material.

Still referring to FIG. 11, the first control terminal (a) of the driving module 101 may include a first gate, and the second control terminal (b) of the driving module 101 may include a second gate. Herein, the second gate of the driving module 101 may be located in the first metal layer M1, and the first gate of the driving module 101 may be located in the second metal layer M2. That is, the first gate of the driving module 101 may be the top gate, and the second gate of the driving module 101 may be the bottom gate. The first gate of the driving module 101 is configured to receive a control signal for controlling the turn-on/turn-off of the driving module 101. The second gate of the driving module 101 is configured to receive an adjustment signal for adjusting the offset state of the threshold voltage of the driving module 101, so as to increase the driving current of the pixel circuit.

It should be noted that display panel 1100 may include a plurality of metal layers located at a side of the active layer 02 away from the first metal layer M1, and the second metal layer M2 may be any one of the plurality of metal layers, which is not limited in the embodiments of the present application.

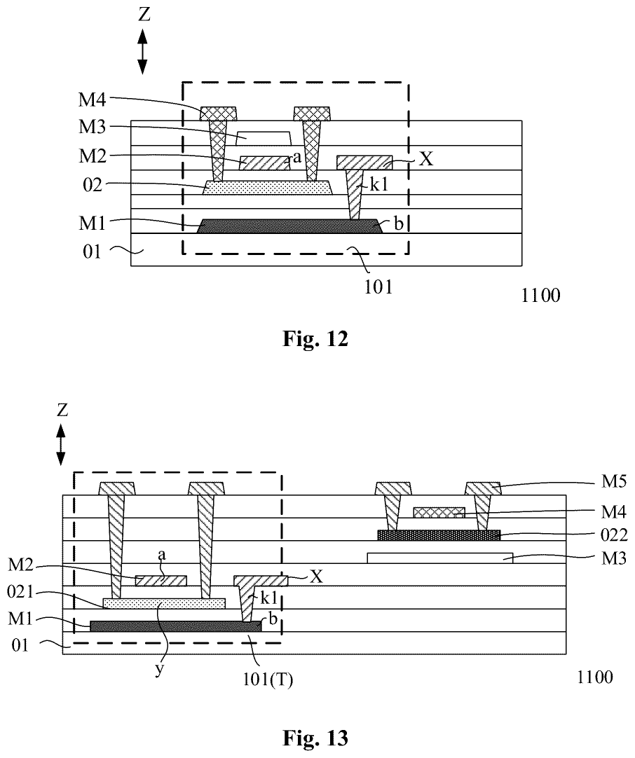

FIG. 12 shows another schematic partial sectional view of a display panel in which the pixel circuit according to the embodiments of the present application is located. As shown in FIG. 12, according to some embodiments of the present application, optionally, the display panel 1100 may further include a third metal layer M3 and a fourth metal layer M4.

Along a thickness direction Z of the display panel, the third metal layer M3 and the fourth metal layer M4 may be located at a side of the second metal layer M2 away from the active layer 02, and the third metal layer M3 is located between the second metal layer M2 and the fourth metal layer M4. In some examples, the first electrode plate of the storage capacitor in the pixel circuit may be located in the second metal layer M2, and the second electrode plate of the storage capacitor may be located in the third metal layer M3. The first terminal and the second terminal of the driving module 101 may be located in the fourth metal layer M4, i.e., the source and the drain of the driving transistor may be located in the fourth metal layer M4.

The adjustment signal line X may be located in the second metal layer M2, the third metal layer M3 or the fourth metal layer M4, and as show in FIG. 12, for example, the adjustment signal line X is located in the second metal layer M2. The second gate of the driving module 101 may be located in the first metal layer M1. The adjustment signal line X may be electrically connected with the second gate of the driving module 101 through a first via k1, and the second gate of the driving module 101 is configured to receive the adjustment signal provided by the adjustment signal line X.

Still referring to FIG. 12, according to some embodiments of the present application, optionally, both of the adjustment signal line X and the first gate of the driving module 101 may be located in the second metal layer M2. Specifically, in practical applications, both of the scanning signal line (such as the first scanning signal line S1 in FIG. 9) and the light emitting control signal line (such as the light emitting control signal line EM in FIG. 7 or FIG. 9) may be located in the second metal layer M2, i.e. gates of the transistors in the pixel circuit are arranged in a same layer and are manufactured by a same mask plate and a same process, the manufacture process is simplified and the number of mask plates is reduced. The adjustment signal line X may reuse the scanning signal line or the light emitting control signal line, therefore both of the adjustment signal line X and the first gate of the driving module 101 may be located in the second metal layer M2.

FIG. 13 shows yet another schematic partial sectional view of a display panel in which the pixel circuit according to the embodiments of the present application is located. As shown in FIG. 13, unlike the embodiments as shown in FIG. 11 or FIG. 12, according to some other embodiments of the present application, optionally, the display panel 1100 may include at least a substrate 01, a first metal layer M1, a first active layer 021, a second metal layer M2, a third metal layer M3, a second active layer 022, and a fourth metal layer M4 that are stacked. Herein, the material of the first active layer 021 may be different from the material of the second active layer 022. For example, in some examples, the material of the first active layer 021 may be an amorphous silicon material or a polycrystalline silicon material for preparing the active area (i.e., the channel area, the source area, and the drain area) of the LTPS transistor. The material of the second active layer 022 may be a metal oxide material for preparing the active area of the oxide transistor. Alternatively, in some other embodiments, the material of the first active layer 021 may be a metal oxide material, and the material of the second active layer 022 may be an amorphous silicon material or a polycrystalline silicon material.

The driving module 101 may include a driving transistor T, the first control terminal (a) of the driving module 101 includes a first gate of the driving transistor T, and the second control terminal (b) of the driving module 101 may include a second gate of the driving transistor T. In the embodiments as shown in FIG. 13, the active area (y) of the driving transistor T may be located in the first active layer 021, the first gate of the driving transistor T may be located in the second metal layer M2, and the second gate of the driving transistor T is located in the first metal layer M1. That is, the first gate of the driving transistor T is the top gate and the second gate of the driving transistor T is the bottom gate. The first gate of the driving transistor T is configured to receive a control signal for controlling the turn-on/turn-off of the driving transistor T. The second gate of the driving transistor T is configured to receive an adjustment signal for adjusting the offset state of the threshold voltage of the driving transistor T, so as to increase the driving current of the pixel circuit.

Still referring to FIG. 13, according to some embodiments of the present application, optionally, the adjustment signal line X may be located in the second metal layer M2, the third metal layer M3, or the fourth metal layer M4. As shown in FIG. 13, for example, the adjustment signal line X is located in the second metal layer M2. If the active area (y) of the driving transistor T is located in the first active layer 021, the adjustment signal line X may be electrically connected with the second gate of the driving transistor T through a first via k1, and the second gate of the driving transistor T is configured to receive the adjustment signal provided by the adjustment signal line X.

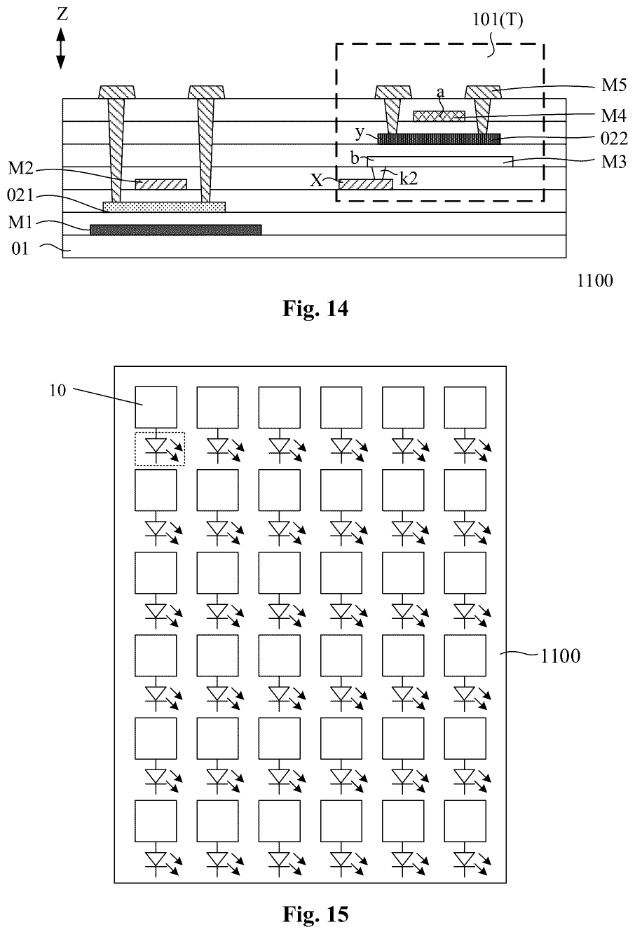

FIG. 14 shows yet another schematic partial sectional view of a display panel in which the pixel circuit according to the embodiments of the present application is located. As shown in FIG. 14, unlike the embodiments as shown in FIG. 13, according to some other embodiments of the present application, optionally, the active area (y) of the driving transistor T may be located in the second active layer 022, the first gate of the driving transistor T may be located in the fourth metal layer M4, and the second gate of the driving transistor T may be located in the third metal layer M3. For example, the driving transistor T may be an oxide transistor. The first gate of the driving transistor T is the top gate, and the second gate of the driving transistor T is the bottom gate. The first gate of the driving transistor T is configured to receive a control signal for controlling the turn-on/turn-off of the driving transistor T. The second gate of the driving transistor T is configured to receive an adjustment signal for adjusting the offset state of the threshold voltage of the driving transistor T, so as to increase the driving current of the pixel circuit.

Still referring to FIG. 14, according to some embodiments of the present application, optionally, the adjustment signal line X may be located in the second metal layer M2, the third metal layer M3, or the fourth metal layer M4. As shown in FIG. 14, for example, the adjustment signal line X is located in the second metal layer M2. In the embodiments as shown in FIG. 14, the adjustment signal line X may be electrically connected with the second gate of the driving transistor T through a second via k2. In other embodiments, the adjustment signal line X may be arranged in the same layer as the second gate of the driving transistor T, for example, both of the adjustment signal line X and the second gate of the driving transistor T are located in the third metal layer M3, so that the number of the second via k2 can be reduced, which is beneficial to the wiring design and wiring space saving.

It should be noted that in some other embodiments, the display panel 1100 may further include other metal layers located at a side of the fourth metal layer M4 away from the second active layer 022, such as a fifth metal layer M5, which is not limited in the embodiments of the present application.

Based on the pixel circuit 10 according to the above embodiments, accordingly, the embodiments of the present application further provide a display panel. FIG. 15 shows a schematic structural diagram of a display panel according to the embodiments of the present application. As shown in FIG. 15, a display panel 1100 according to the embodiments of the present application may include the pixel circuit 10 according to the above embodiments. The circuit structures of the pixel circuit 10 and the cross-sectional structures of the display panel 1100 have been described in detail above and will not be repeated herein.

In some embodiments, the display panel 1100 includes, but is not limited to, a LTPS display panel or a LTPO display panel.

In some embodiments, the display panel 1100 includes, but is not limited to, a micro LED display panel, a mini LED display panel, an OLED display panel, or a QLED display panel.

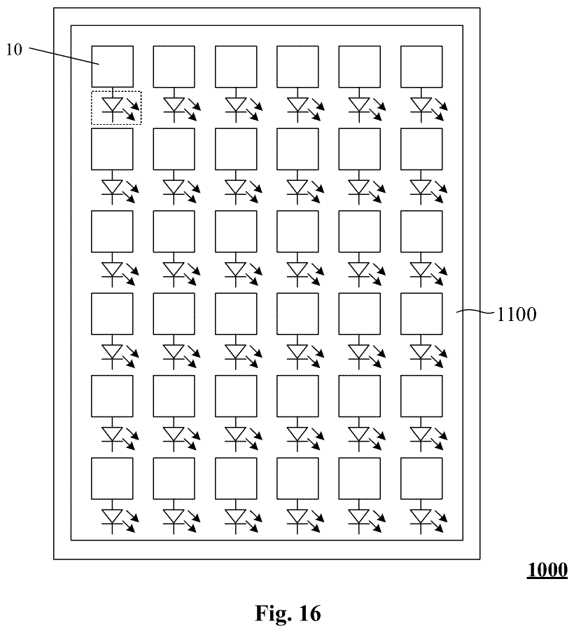

Based on the pixel circuit 10 and the display panel 1100 according to the above embodiments, accordingly, the embodiments of the present application further provide a display apparatus including the pixel circuit 10 or the display panel 1100 according to the present application. Referring to FIG. 16, which shows a schematic structural diagram of a display apparatus according to the embodiments of the present application. The display apparatus 1000 as shown in FIG. 16 includes the pixel circuit 10 or the display panel 1100 according to any of the above embodiments of the present application. The embodiments of FIG. 16 illustrates the display apparatus 1000 by, for example, using a cell phone as an example, and it may be understood that, the display apparatus according to the embodiments of the present application may be a wearable product, a computer, a television, a on-board display apparatus, and other display apparatus with a display function, which is not specifically limited in the present application. The display apparatus according to the embodiments of the present application has the beneficial effects of the pixel circuit 10 or display panel 1100 according to the embodiments of the present application, and reference is made to the specific description of the pixel circuit 10 or display panel 1100 in the above embodiments, which will not be repeated herein.

It should be understood that the specific structures of the circuit and the cross-sectional structures of the display panel provided in the accompanying drawings of the embodiments of the present application are only examples, and are not intended to limit the present application. In addition, the above embodiments of present application may be combined without conflict.

It should be noted that various embodiments in the present specification are described in a progressive manner, the same or similar parts among various embodiment can refer to each other, and each of the embodiment focuses on the differences with other embodiments. The above embodiments of the present application do not exhaustively describe all the details and do not limit the present application to only the specific embodiments described. Obviously, many modifications and variations can be made based on the above description. These embodiments are selected and specifically described in the description to better explain the principles and practical applications of the present application, so that those skilled in the art can make good use of the present application and make modifications based on the present application. The present application is limited only by the claims, along with their full scope and equivalents.

Those skilled in the art can understand that all the above embodiments are exemplary and not limiting. Different technical features in different embodiments can be combined to achieve beneficial effects. Those skilled in the art can understand and implement other variations of the disclosed embodiments after studying the accompanying drawings, the specification and claims. In the claims, the term “comprise” does not exclude other structures; the number relates to “a” but does not exclude more than one; and the terms “first”, “second” are used to designate names rather than to indicate any particular order. Any reference numeral in the claims should not be construed as limiting the scope of protection. The presence of certain technical features in different dependent claims does not indicate that these technical features cannot be combined to achieve beneficial effects.

What is claimed is:

1. A pixel circuit, comprising:
a driving module comprising a first control terminal for receiving a control signal and a second control terminal for receiving an adjustment signal, wherein
a voltage value of the adjustment signal is a first voltage value when the driving module operates in a first stage and is a second voltage value when the driving module operates in a second stage, and the first voltage value is different from the second voltage value.

2. The pixel circuit of claim 1, wherein the driving module is in an on state in the first stage and the second stage.

3. The pixel circuit of claim 1, wherein an offset direction of a threshold voltage of the driving module in the first stage is different from an offset direction of the threshold voltage of the driving module in the second stage.

4. The pixel circuit of claim 1, wherein the first stage comprises a data writing stage and the second stage comprises a light emitting stage.

5. The pixel circuit of claim 4, wherein the driving module comprises a transistor of first conductive type, a data signal is written into the transistor of first conductive type in the data writing stage, and the first voltage value is greater than 0 V.

6. The pixel circuit of claim 4, wherein the driving module comprises a transistor of first conductive type, and the second voltage value is less than the first voltage value.

7. The pixel circuit of claim 6, wherein the second voltage value is less than 0 V.

8. The pixel circuit of claim 6, wherein the first voltage value is in a range of 0 V to 10 V and/or the second voltage value is in a range of −10 V to 0 V.

9. The pixel circuit of claim 4, wherein the driving module comprises a transistor of second conductive type, a data signal is written into the transistor of second conductive type in the data writing stage, and the first voltage value is less than 0 V.

10. The pixel circuit of claim 4, wherein the driving module comprises a transistor of second conductive type, and the second voltage value is greater than the first voltage value.

11. The pixel circuit of claim 10, wherein the second voltage value is greater than 0 V.

12. The pixel circuit of claim 1, wherein the second control terminal of the driving module is electrically connected with an adjustment signal line and configured to receive the adjustment signal provided by the adjustment signal line, and the adjustment signal is configured to adjust an offset state of a threshold voltage of the driving module.

13. The pixel circuit of claim 12, further comprising:
a switching module comprising a control terminal being electrically connected with a light emitting control signal line or a scanning signal line and a first terminal being electrically connected with a first terminal or a second terminal of the driving module, wherein
the light emitting control signal line or the scanning signal line is reused as the adjustment signal line.

14. The pixel circuit of claim 13, wherein the switching module comprises a threshold compensation module comprising a control terminal being electrically connected with a first scanning signal line, a first terminal being electrically connected with the first control terminal of the driving module, and a second terminal being electrically connected with the second terminal of the driving module;
the threshold compensation module and the driving module are transistors of different conductive types; and
the first scanning signal line is reused as the adjustment signal line.

15. The pixel circuit of claim 1, wherein the driving module comprises a driving transistor, and a width-length ratio of a channel of the driving transistor is greater than 1/10.

16. The pixel circuit of claim 1, further comprising:
a threshold compensation module comprising a control terminal being electrically connected with a first scanning signal line, a first terminal being electrically connected with the first control terminal of the driving module, and a second terminal being electrically connected with a second terminal of the driving module;
a data writing module comprising a control terminal being electrically connected with a second scanning signal line, a first terminal being electrically connected with a data signal line, and a second terminal being electrically connected with a first terminal of the driving module;
a first resetting module comprising a control terminal being electrically connected with a third scanning signal line, a first terminal being electrically connected with a first reference voltage signal line, and a second terminal being electrically connected with the first control terminal of the driving module;
a second resetting module comprising a control terminal being electrically connected with a fourth scanning signal line, a first terminal being electrically connected with a second reference voltage signal line, and a second terminal being electrically connected with a first electrode of a light emitting element;
a first light emitting control module comprising a control terminal being electrically connected with a light emitting control signal line, a first terminal being electrically connected with a first supply voltage signal line, and a second terminal being electrically connected with the first terminal of the driving module;
a second light emitting control module comprising a control terminal being electrically connected with the light emitting control signal line, a first terminal being electrically connected with the second terminal of the driving module, and a second terminal being electrically connected with the first electrode of the light emitting element; and
a storage module comprising a first terminal being electrically connected with the first supply voltage signal line and a second terminal being electrically connected with the first control terminal of the driving module.

17. The pixel circuit of claim 1, wherein the pixel circuit is applied to a display panel comprising at least a substrate, a first metal layer, an active layer and a second metal layer being stacked; and
the first control terminal comprises a first gate being located in the second metal layer, and the second control terminal comprises a second gate being located in the first metal layer.

18. The pixel circuit of claim 17, wherein the display panel further comprises a third metal layer and a fourth metal layer;
along a thickness direction of the display panel, the third metal layer and the fourth metal layer are located at a side of the second metal layer away from the active layer, and the third metal layer is located between the second metal layer and the fourth metal layer;
the second gate of the driving module is electrically connected with an adjustment signal line and configured to receive the adjustment signal provided by the adjustment signal line; and
the adjustment signal line is located in the second metal layer, the third metal layer or the fourth metal layer and electrically connected with the second gate through a first via.

19. The pixel circuit of claim 18, wherein the adjustment signal line and the first gate are both located in the second metal layer.

20. The pixel circuit of claim 1, wherein the pixel circuit is applied to a display panel comprising at least a substrate, a first metal layer, a first active layer, a second metal layer, a third metal layer, a second active layer and a fourth metal layer being stacked;
the driving module comprises a driving transistor, the first control terminal comprises a first gate of the driving transistor, and the second control terminal comprises a second gate of the driving transistor;
an active area of the driving transistor is located in the first active layer, the first gate is located in the second metal layer, and the second gate is located in the first metal layer; or
the active area of the driving transistor is located in the second active layer, the first gate is located in the fourth metal layer, and the second gate is located in the third metal layer.

21. The pixel circuit of claim 20, wherein the second gate of the driving module is electrically connected with an adjustment signal line and configured to receive the adjustment signal provided by the adjustment signal line;
the adjustment signal line is located in the second metal layer, the third metal layer or the fourth metal layer;
when the active area of the driving transistor is located in the first active layer, the adjustment signal line is electrically connected with the second gate through a first via; or
when the active area of the driving transistor is located in the second active layer, the adjustment signal line and the second gate are arranged in a same layer, or the adjustment signal line is electrically connected with the second gate through a second via.

22. A display panel comprising a pixel circuit, the pixel circuit comprising:
a driving module comprising a first control terminal for receiving a control signal and a second control terminal for receiving an adjustment signal, wherein
a voltage value of the adjustment signal is a first voltage value when the driving module operates in a first stage and is a second voltage value when the driving module operates in a second stage, and the first voltage value is different from the second voltage value.

23. A display apparatus comprising a display panel, the display panel comprising a pixel circuit, and the pixel circuit comprising:
a driving module comprising a first control terminal for receiving a control signal and a second control terminal for receiving an adjustment signal, wherein
a voltage value of the adjustment signal is a first voltage value when the driving module operates in a first stage and is a second voltage value when the driving module operates in a second stage, and the first voltage value is different from the second voltage value.
